(19) United States
(12) Patent Application Publication
(10) Pub. No.: US 2008/0246139 A1
(43) Pub. Date: Oct. 9, 2008

(54) Polar hybrid grid array package

(76) Inventors: Don Craven, Maple Valley, WA (US); Joseph G. Militello, El Dorado Hills, CA (US); Eugene Nelson, Olympia, WA (US)

Correspondence Address: LeMOINE PATENT SERVICES, PLLC, C/O INTELLEVATE, P. O. BOX 52050, MINNEAPOLIS, MN, 55402, US

(21) Appl. No.: 11/732,336

(22) Filed: Apr. 3, 2007

(51) Int. Cl. H01L 23/488; H01L 21/44

(52) U.S. Cl. 257/693; 438/613; 257/E21.476; 257/E23.023

(57) ABSTRACT

A grid array package includes a rectangular pattern of electrical contacts around a perimeter of the package. The grid array package also includes a polar pattern of electrical contacts inside of, and concentric with, the rectangular pattern. The grid array package also includes additional electrical contacts arranged between the rectangular pattern and the polar pattern.

### FIELD

The present invention relates generally to integrated circuits, and more specifically to packages for integrated circuits.

### BACKGROUND

Grid array packages are known in the art. Typical grid array packages include electrical contacts such as solder balls arranged in a regular pattern. For example, solder balls are often arranged on a fixed grid, resulting a large rectangular grid of solder balls.

### BRIEF DESCRIPTION OF THE DRAWINGS

FIG. 1 shows a side view of an integrated circuit and a package;

FIG. 2 shows a plan view of a bottom side of a polar hybrid grid array package;

FIG. 3 shows a flowchart in accordance with various embodiments of the present invention; and

FIGS. 4 and 5 show diagrams of electronic systems in accordance with various embodiments of the present invention.

### DESCRIPTION OF EMBODIMENTS

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein in connection with one embodiment may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

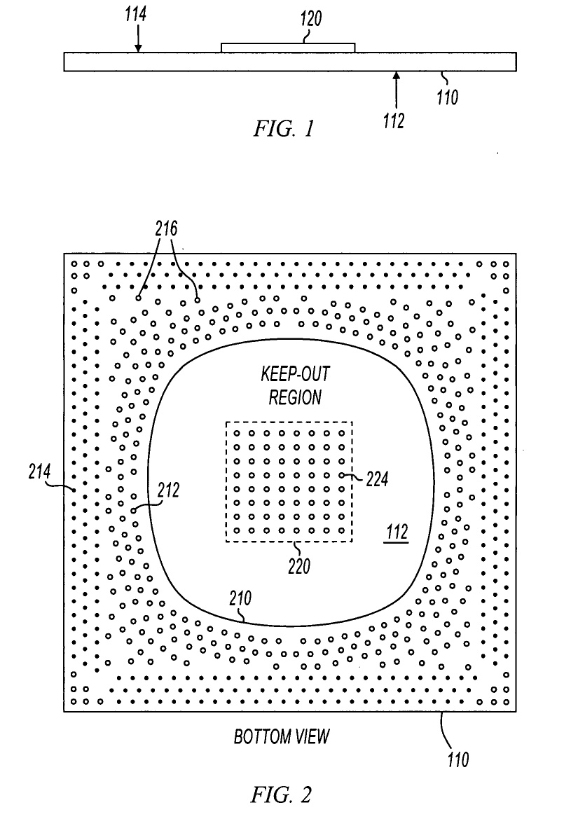

FIG. 1 shows a side view of an integrated circuit and a package. Grid array package 110 includes two sides, top side 114 and bottom side 112. Integrated circuit 120 is affixed to grid array package 110 on top side 114. Integrated circuit 120 may be affixed in any manner. For example, in some embodiments, integrated circuit 120 may be a flip-chip application in which electrical contact is made at the junction of integrated circuit 120 and top side 114. Also for example, in some embodiments, integrated circuit 120 may be situated with contacts on the top side, and bond wires (not shown) may provide conductivity between integrated circuit 120 and package 110.

Grid array package 110 may have electrical contacts on bottom side 112 to provide electrical connections to a circuit board. For example, solder balls (not shown) may be present on bottom side 112. Various embodiments of the present invention have solder balls arranged in a hybrid pattern that includes rectangular patterns and polar patterns. These embodiments are further described below with respect to the remaining figures.

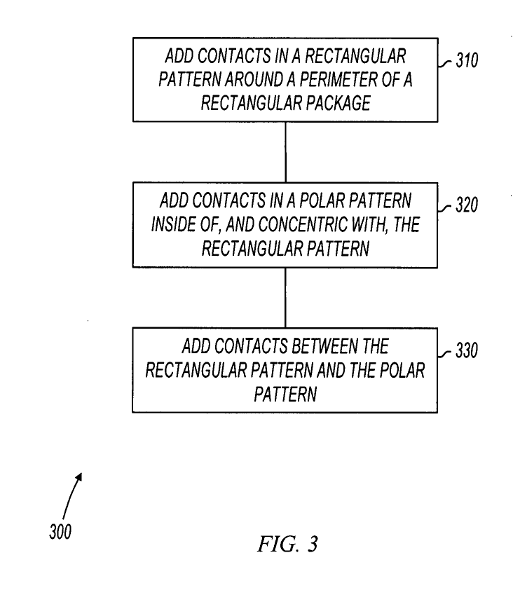

FIG. 2 shows a plan view of a bottom side of a polar hybrid grid array package. Bottom side 112 of package 110 includes electrical contacts in multiple geometric patterns. The electrical contacts are referred to henceforth as solder balls, but the invention is not so limited. Any type of electrical contact may be utilized without departing from the scope of the present invention.

Solder balls are arranged around the perimeter in a rectangular pattern. For example, solder balls 214 are arranged in a rectangular fashion. In some embodiments, three rectangles of solder balls are included about the perimeter, but the invention is not so limited. Any number of rectangular patterns may be about the perimeter of the package.

Solder balls are arranged in a polar pattern inside the rectangular patterns. For example, solder balls 212 are arranged in a polar pattern. As used herein, the term “polar pattern” refers to any pattern other than rectangular that includes solder balls that can be located in a polar coordinate system. In some embodiments, the polar pattern includes solder balls arranged in concentric circles. In other embodiments, the solder balls are arranged in semi-circular concentric patterns. Any number of concentric rings of solder balls may be included in the polar pattern. In the example of FIG. 2, three concentric semi-circular rings of solder balls 212 are shown.

Solder balls 216 are situated between the rectangular pattern and the polar pattern. Solder balls 216 may be placed in any geometric manner, including any irregular pattern or randomly. Solder balls 224 are placed beneath the integrated circuit, the outline of which is shown at 220.

A “keep-out” region is defined between integrated circuit boundary 220 and outer boundary 210. The term “keep-out” is used to refer to an area that solder balls are not to be placed. In some embodiments, the keep-out region may be used for vias in the package, wire bonding on the top side, or any other use that either prohibits or creates problems for solder ball placement. The various embodiments of the present invention are not limited by the reason for the existence of the keep-out region.

In some embodiments, the outer boundary 210 of the keep-out region is not rectangular. For example, in the example of FIG. 2, the outer boundary is semi-circular. The various embodiments of the present invention include a polar pattern of solder balls just outside the keep-out region, a rectangular pattern of solder balls at the perimeter of the package, and additional solder balls to fill in the space between the polar and rectangular patterns.

In some embodiments, the solder balls are not uniform in size. For example, solder balls 214 are shown smaller than solder balls 212, 216 and 224. In some embodiments, the rectangular pattern includes solder balls 12 mils and 16 mils in diameter, and the polar pattern includes solder balls 14 mils in diameter. Any combination of solder ball sizes may be utilized without departing from the scope of the present invention.

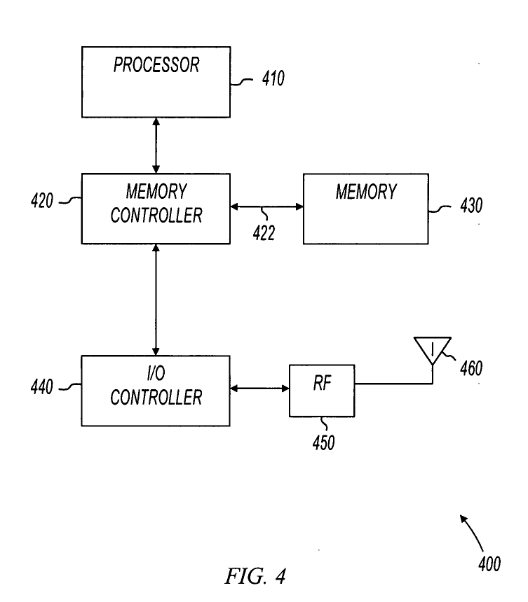

FIG. 3 shows a flowchart in accordance with various embodiments of the present invention. In some embodiments, method 300 may be used to design or fabricate a polar hybrid grid array package. In some embodiments, method 300, or portions thereof, is performed by a design automation tool, and in other embodiments, method 300, or portions thereof, is performed by manufacturing equipment. The various actions in method 300 may be performed in the order presented, in a different order, or simultaneously. Further, in some embodiments, some actions listed in FIG. 3 are omitted from method 300.

Method 300 begins at 310 in which contacts are added in a rectangular pattern around a perimeter of a rectangular package. At 320, contacts are added in a polar pattern inside of, and concentric with, the rectangular pattern. At 330, contacts are added between the rectangular pattern and the polar pattern.

Any number concentric rings of contacts may be added at 310 and 320. For example, at 310, three rectangles of contacts may be added about the perimeter, and at 320, three polar rings of contacts may be added outside the keep-out region. The polar pattern may be circular, semi-circular, oval, or any other non-rectangular shape. In some embodiments, the electrical contacts include solder balls.

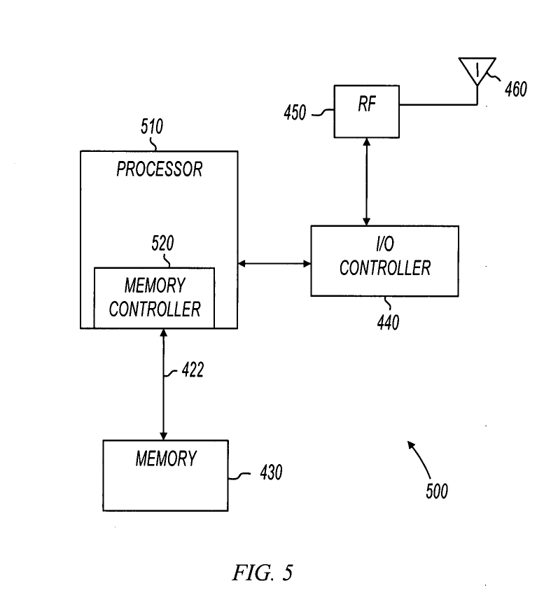

FIG. 4 shows an electronic system in accordance with various embodiments of the present invention. Electronic system 400 includes processor 410, memory controller 420, memory 430, input/output (I/O) controller 440, radio frequency (RF) circuits 450, and antenna 460. In operation, system 400 sends and receives signals using antenna 460, and these signals are processed by the various elements shown in FIG. 4. Antenna 460 may be a directional antenna or an omni-directional antenna. As used herein, the term omni-directional antenna refers to any antenna having a substantially uniform pattern in at least one plane. For example, in some embodiments, antenna 460 may be an omni-directional antenna such as a dipole antenna, or a quarter wave antenna. Also for example, in some embodiments, antenna 460 may be a directional antenna such as a parabolic dish antenna, a patch antenna, or a Yagi antenna. In some embodiments, antenna 460 may include multiple physical antennas.

Radio frequency circuit 450 communicates with antenna 460 and I/O controller 440. In some embodiments, RF circuit 450 includes a physical interface (PHY) corresponding to a communications protocol. For example, RF circuit 450 may include modulators, demodulators, mixers, frequency synthesizers, low noise amplifiers, power amplifiers, and the like. In some embodiments, RF circuit 450 may include a heterodyne receiver, and in other embodiments, RF circuit 450 may include a direct conversion receiver. In some embodiments, RF circuit 450 may include multiple receivers. For example, in embodiments with multiple antennas 460, each antenna may be coupled to a corresponding receiver. In operation, RF circuit 450 receives communications signals from antenna 460, and provides analog or digital signals to I/O controller 440. Further, I/O controller 440 may provide signals to RF circuit 450, which operates on the signals and then transmits them to antenna 460.

Processor 410 may be any type of processing device. For example, processor 410 may be a microprocessor, a microcontroller, or the like. Further, processor 410 may include any number of processing cores, or may include any number of separate processors.

Memory controller 420 provides a communications path between processor 410 and other devices shown in FIG. 4. In some embodiments, memory controller 420 is part of a hub device that provides other functions as well. As shown in FIG. 4, memory controller 420 is coupled to processor 410, I/O controller 440, and memory 430.

Memory 430 may be any type of memory technology. For example, memory 430 may be random access memory (RAM), dynamic random access memory (DRAM), static random access memory (SRAM), nonvolatile memory such as FLASH memory, or any other type of memory.

Memory 430 may represent a single memory device or a number of memory devices on one or more memory modules. Memory controller 420 provides data through bus 422 to memory 430 and receives data from memory 430 in response to read requests. Commands and/or addresses may be provided to memory 430 through conductors other than bus 422 or through bus 422. Memory controller 430 may receive data to be stored in memory 430 from processor 410 or from another source. Memory controller 420 may provide the data it receives from memory 430 to processor 410 or to another destination. Bus 422 may be a bidirectional bus or unidirectional bus. Bus 422 may include many parallel conductors. The signals may be differential or single ended.

Memory controller 420 is also coupled to I/O controller 440, and provides a communications path between processor 410 and I/O controller 440. I/O controller 440 includes circuitry for communicating with I/O circuits such as serial ports, parallel ports, universal serial bus (USB) ports, and the like. As shown in FIG. 4, I/O controller 440 provides a communications path to RF circuits 450.

In various embodiments of the present invention, one or more of the integrated circuits in system 400 includes a polar hybrid grid array package. For example, memory controller 420 may be a packaged integrated circuit that has rectangular, polar, and irregular patterned solder balls. Any of the embodiments described herein may be utilized with any of the circuits of system 400.

FIG. 5 shows an electronic system in accordance with various embodiments of the present invention. Electronic system 500 includes memory 430, I/O controller 440, RF circuits 450, and antenna 460, all of which are described above with reference to FIG. 4. Electronic system 500 also includes processor 510 and memory controller 520. As shown in FIG. 5, memory controller 520 is included in processor 510. Processor 510 may be any type of processor as described above with reference to processor 410 (FIG. 4). Processor 510 differs from processor 410 in that processor 510 includes memory controller 520, whereas processor 410 does not include a memory controller.

Example systems represented by FIGS. 4 and 5 include desktop computers, laptop computers, cellular phones, personal digital assistants, wireless local area network interfaces, or any other suitable system. Many other systems uses for integrated circuits packaged in polar hybrid grid array packaged exist. For example, the various embodiments described herein may be used in a server computer, a network bridge or router, or any other system with or without an antenna.

Further, systems represented by FIGS. 4 and 5 may be systems capable of performing the design of a polar hybrid grid array package. For example, instructions for the various method embodiments of the present invention may be stored in memory 430, and processor 410 or processor 510 may perform the operations associated with the methods.

Although the present invention has been described in conjunction with certain embodiments, it is to be understood that modifications and variations may be resorted to without departing from the spirit and scope of the invention as those skilled in the art readily understand. Such modifications and variations are considered to be within the scope of the invention and the appended claims.

What is claimed is:

1. A grid array package comprising:
a first plurality of electrical contacts arranged in a rectangular pattern about a perimeter of the grid array package; and
a second plurality of electrical contacts arranged in a non-rectangular pattern inside the first plurality of electrical contacts.

2. The grid array package of claim 1 wherein the second plurality of electrical contacts are arranged in a polar pattern concentric with the rectangular pattern.

3. The grid array package of claim 2 further comprising a third plurality of electrical contacts arranged to fill in space between the first and second pluralities of electrical contacts.

4. The grid array package of claim 3 wherein the polar pattern is substantially circular.

5. The grid array package of claim 1 further comprising a rectangular grid of electrical contacts in a center of the package.

6. A packaged integrated circuit comprising:
an integrated circuit die; and
a rectangular package to which the integrated circuit die is affixed, the rectangular package having a non-rectangular keep-out region existing around the integrated circuit die, the rectangular package further having solder balls on a side opposite the integrated circuit die, the solder balls arranged in a rectangular pattern about a perimeter of the package and arranged in a non-rectangular pattern between the keep-out region and the perimeter.

7. The packaged integrated circuit of claim 6 wherein the rectangular pattern includes at least three concentric rectangles of solder balls.

8. The packaged integrated circuit of claim 7 wherein the non-rectangular pattern includes a polar pattern of solder balls outside the keep-out region.

9. The packaged integrated circuit of claim 8 wherein the non-rectangular pattern further includes solder balls placed between the polar pattern and the rectangular pattern.

10. The packaged integrated circuit of claim 8 wherein the polar pattern is a substantially circular pattern.

11. A method comprising:
adding contacts in a rectangular pattern around a perimeter of a rectangular package;
adding contacts in a polar pattern inside of, and concentric with, the rectangular pattern; and
adding contacts between the rectangular pattern and the polar pattern.

12. The method of claim 11 wherein adding contacts in a rectangular pattern comprises adding at least three concentric rectangles of contacts.

13. The method of claim 11 wherein adding contacts in a polar pattern comprises adding at least three rings of contacts in a concentric polar pattern.

14. The method of claim 11 wherein adding contacts in a polar pattern comprises adding contacts in a substantially circular pattern.

15. The method of claim 11 further comprising adding a rectangular grid of contacts in a center of the rectangular package.

16. The method of claim 11 wherein the contacts comprise solder balls.

17. The method of claim 11 wherein adding contacts between the rectangular pattern and the polar pattern comprises adding contacts in a non-uniform pattern to maximize area usage.

18. A system comprising:
an antenna;
radio frequency circuit coupled to the antenna; and
an integrated circuit coupled to the radio frequency circuit, the integrated circuit having a grid array package comprising a first plurality of electrical contacts arranged in a rectangular pattern about a perimeter of the grid array package, and a second plurality of electrical contacts arranged in a non-rectangular pattern inside the first plurality of electrical contacts.

19. The system of claim 18 wherein the second plurality of electrical contacts are arranged in a polar pattern concentric with the rectangular pattern.

20. The system of claim 19 wherein the grid array package further comprises a third plurality of electrical contacts arranged to fill in space between the first and second pluralities of electrical contacts.
